(19) United States
(12) Patent Application Publication
(10) Pub. No.: US 2025/0264504 A1
(43) Pub. Date: Aug. 21, 2025

(54) VOLTAGE MEASUREMENT ASSEMBLY AND SUBSTRATE CHARGING MEASUREMENT METHOD USING THE SAME

(71) Applicant: Samsung Electronics Co., Ltd., Suwon-si (KR)

(72) Inventors: Young Yoon, Suwon-si (KR); Nam Kyun Kim, Suwon-si (KR); Kyung-Sun Kim, Suwon-si (KR); Jongmin Song, Suwon-si (KR); Younsok Choi, Suwon-si (KR)

(21) Appl. No.: 18/812,032

(22) Filed: Aug. 22, 2024

(30) Foreign Application Priority Data
Feb. 15, 2024 (KR) 10-2024-0022073

(51) Int. Cl. G01R 19/00; G01R 1/073

(52) U.S. Cl. CPC G01R 19/0084; G01R 1/07314

(57) ABSTRACT

Disclosed are voltage measurement assemblies and substrate charging measurement methods. The voltage measurement assembly includes a support substrate, and a voltage measurement probe on a top surface of the support substrate. The voltage measurement probe includes a first electrode, a pattern plate, a dielectric wall in contact with a lateral surface of the pattern plate, and a second electrode in contact with the dielectric wall. The pattern plate provides a plurality of pattern holes that are downwardly recessed from a top surface of the pattern plate and vertically extend in the pattern plate. The second electrode does not vertically overlap the first electrode.

### CROSS-REFERENCE TO RELATED APPLICATION

This U.S. nonprovisional application claims priority under 35 U.S.C § 119 to Korean Patent Application No. 10-2024-0022073 filed on Feb. 15, 2024 in the Korean Intellectual Property Office, the disclosure of which is hereby incorporated by reference in its entirety.

### BACKGROUND

The present inventive concepts relate generally to a voltage measurement assembly and a substrate charging measurement method using the same, and more particularly, to a voltage measurement assembly capable of measuring the degree of substrate charging under an environment similar to an actual process environment and a substrate charging measurement method using the same.

A semiconductor device may be fabricated through various processes. For example, the semiconductor device may be manufactured through a photolithography process, an etching process, a deposition process, and a plating process on a substrate. A plasma may be used in a substrate process. For example, a substrate may be etched with the plasma in an etching process on the substrate. The substrate may be charged in the substrate etching process using the plasma.

### SUMMARY

Some embodiments of the present inventive concepts provide a voltage measurement assembly capable of estimating a substrate charging state under an environment similar to that of a substrate etching process and a substrate charging measurement method using the same.

Some embodiments of the present inventive concepts provide a voltage measurement assembly capable of concurrently obtaining measurement results for various substrate positions and a substrate charging measurement method using the same.

Some embodiments of the present inventive concepts provide a voltage measurement assembly capable of concurrently obtaining measurement results for various aspect ratios and a substrate charging measurement method using the same.

Some embodiments of the present inventive concepts provide a voltage measurement assembly capable of eliminating measurement errors possibly occurring due to voltage distortion and/or simulation of electrical characteristics of an actual process substrate and a substrate charging measurement method using the same.

Objects of the present inventive concepts are not limited to those mentioned above, and other objects which have not been mentioned above will be clearly understood to those skilled in the art from the following description.

According to some embodiments of the present inventive concepts, a voltage measurement assembly may comprise: a support substrate; and a voltage measurement probe on a top surface of the support substrate. The voltage measurement probe may include: a first electrode; a pattern plate; a dielectric wall combined with a lateral surface of the pattern plate; and a second electrode combined with the dielectric wall. The pattern plate may provide a plurality of pattern holes that are downwardly recessed from a top surface of the pattern plate and vertically penetrate (i.e., extend into or through) the pattern plate. The second electrode may not overlap the first electrode.

According to some embodiments of the present inventive concepts, a voltage measurement assembly may comprise: a support substrate; and a plurality of voltage measurement probes on the support substrate. Each of the plurality of voltage measurement probes may include: a first electrode; a pattern plate on the first electrode; a dielectric wall outside the pattern plate; and a second electrode combined with the dielectric wall. The pattern plate may provide a plurality of pattern holes that vertically penetrate the pattern plate to expose a top surface of the first electrode.

According to some embodiments of the present inventive concepts, a substrate charging measurement method may comprise: inserting a voltage measurement assembly into a substrate processing apparatus; and using the voltage measurement assembly to measure a voltage. The voltage measurement assembly may include a voltage measurement probe. The voltage measurement probe may include: a first electrode; a pattern plate on the first electrode, the pattern plate providing a plurality of pattern holes that expose the first electrode; a dielectric wall combined with a lateral surface of the pattern plate; and a second electrode connected to the dielectric wall, the second electrode not overlapping the pattern plate. The step of using the voltage measurement assembly to measure the voltage may include measuring a voltage of the first electrode and a voltage of the second electrode.

Details of other example embodiments are included in the following description and the accompanying drawings, wherein like reference numerals (when used) indicate corresponding elements throughout the several views.

### BRIEF DESCRIPTION OF DRAWINGS

FIG. 1 illustrates a schematic plan view showing a voltage measurement assembly according to some embodiments of the present inventive concepts.

FIG. 2 illustrates a schematic plan view showing a voltage measurement probe according to some embodiments of the present inventive concepts.

FIG. 3 illustrates a schematic side cross-sectional view partially showing a voltage measurement assembly according to some embodiments of the present inventive concepts.

FIG. 4 illustrates a schematic side cross-sectional view showing a voltage measurement probe according to some embodiments of the present inventive concepts.

FIG. 5 illustrates a flow diagram showing a substrate charging measurement method according to some embodiments of the present inventive concepts.

FIGS. 6 to 11 illustrate schematic diagrams showing a substrate charging measurement method according to the flow diagram of FIG. 5.

FIG. 12 illustrates a schematic side cross-sectional view partially showing a voltage measurement assembly according to some embodiments of the present inventive concepts.

FIG. 13 illustrates a schematic side cross-sectional view partially showing a voltage measurement assembly according to some embodiments of the present inventive concepts.

FIG. 14 illustrates a schematic side cross-sectional view showing a voltage measurement probe according to some embodiments of the present inventive concepts.

FIG. 15 illustrates a schematic plan view showing a voltage measurement assembly according to some embodiments of the present inventive concepts.

FIG. 16 illustrates a schematic side cross-sectional view taken along line I-I′ of FIG. 15.

FIG. 17 illustrates a schematic side cross-sectional view partially showing a voltage measurement assembly according to some embodiments of the present inventive concepts.

FIG. 18 illustrates a schematic plan view showing a voltage measurement probe according to some embodiments of the present inventive concepts.

FIG. 19 illustrates a schematic side cross-sectional view partially showing a voltage measurement assembly according to some embodiments of the present inventive concepts.

### DETAILED DESCRIPTION

The following will now describe some embodiments of the present inventive concepts with reference to the accompanying drawings. Like reference numerals may indicate like components throughout the description.

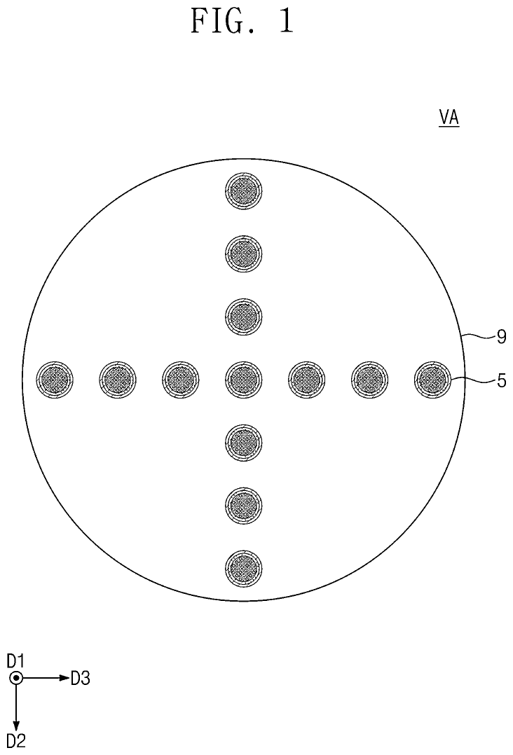

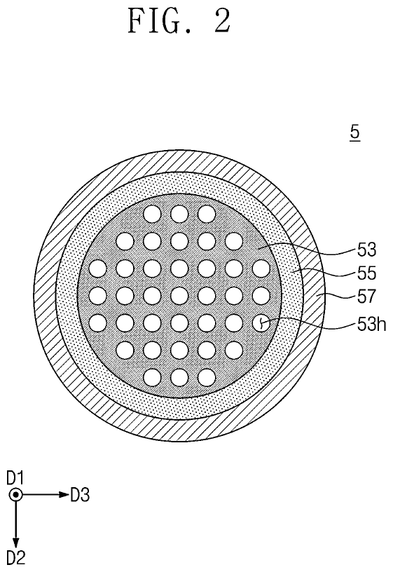

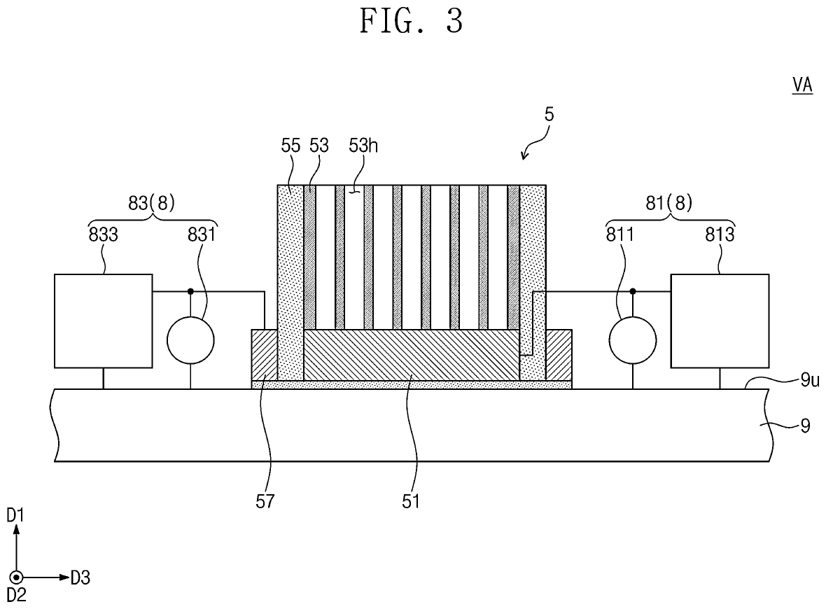

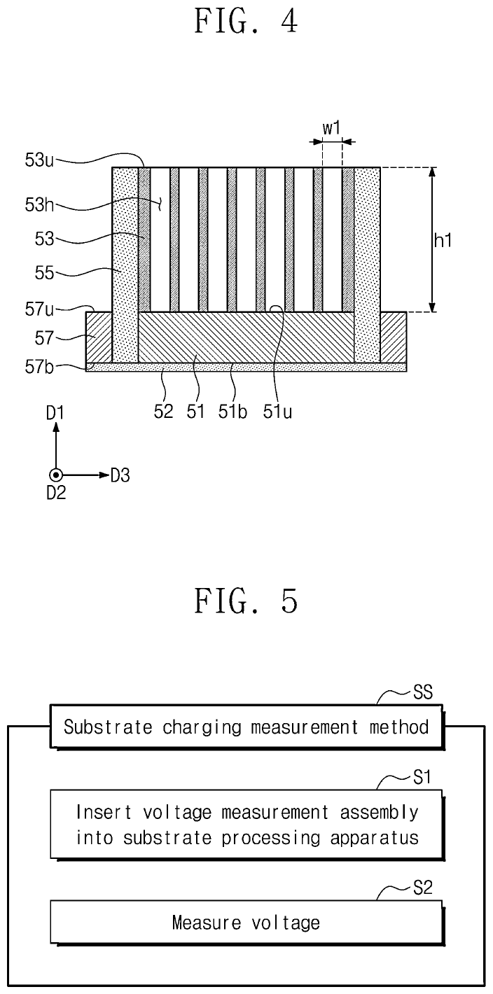

FIG. 1 illustrates a schematic plan view showing a voltage measurement assembly according to some embodiments of the present inventive concepts. FIG. 2 illustrates a schematic plan view showing a voltage measurement probe according to some embodiments of the present inventive concepts. FIG. 3 illustrates a schematic side cross-sectional view partially showing a voltage measurement assembly according to some embodiments of the present inventive concepts. FIG. 4 illustrates a schematic side cross-sectional view showing a voltage measurement probe according to some embodiments of the present inventive concepts.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be called an upward direction, and a direction opposite to the first direction D1 may be called a downward direction. Alternatively, the first direction D1 may be called a vertical direction. Each of the second direction D2 and the third direction D3 may be called a horizontal direction.

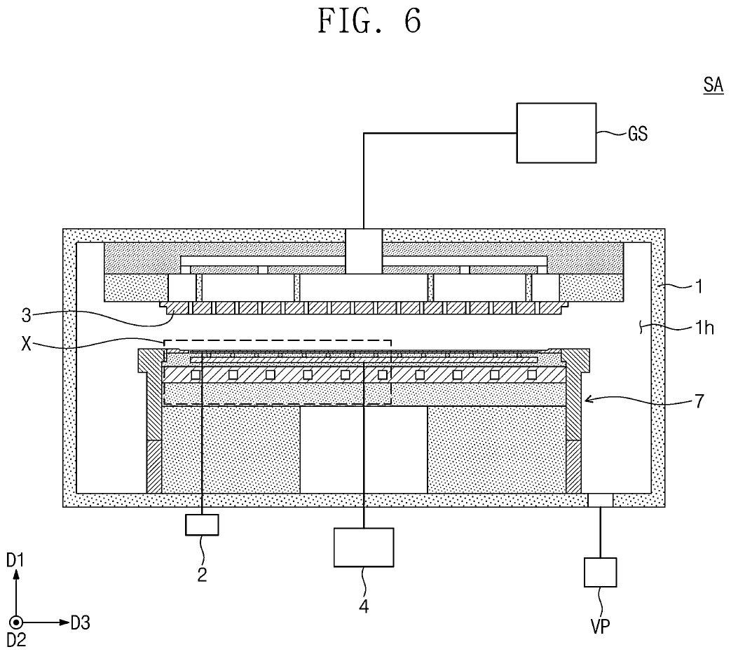

Referring to FIGS. 1 to 4, a voltage measurement assembly VA may be provided. The voltage measurement assembly VA may be inserted into a substrate processing apparatus (see, e.g., SA of FIG. 6) to execute a measurement process. The use of data measured by using the substrate measurement assembly VA may estimate (i.e., anticipate) the degree of substrate charging during a substrate process performed in the substrate processing apparatus SA. A substrate processed by the substrate processing apparatus SA may include a silicon (Si) wafer and/or a silicon oxide (SiO₂) wafer, but the present inventive concepts are not limited thereto. Before a process is performed on the substrate, the voltage measurement assembly VA whose shape is similar to that of the substrate may be inserted into the substrate processing apparatus SA to thereby measure a voltage distribution. It may thus be possible to estimate in advance the degree of substrate charging during a substrate process performed in the substrate processing apparatus SA. The voltage measurement assembly VA may include a support substrate 9, a voltage measurement probe 5, and a voltage measurement device 8.

The support substrate 9 may support the voltage measurement probe 5. For example, the voltage measurement probe 5 may be disposed on a top surface 9u of the support substrate 9. The support substrate 9 may have a shape similar to that of a substrate that is inserted into the substrate processing apparatus SA. For example, the support substrate 9 may have a disk shape. The support substrate 9 may have a wafer-like appearance. The support substrate 9 may have a diameter, for example, ranging from about 280 mm to about 320 mm. For example, the support substrate 9 may have a diameter of about 300 mm. The support substrate 9 may include one or more of quartz (e.g., silicon dioxide (SiO₂)), silicon (Si), and metal, but the present inventive concepts are not limited thereto.

The voltage measurement probe 5 may be positioned on the support substrate 9. The voltage measurement probe 5 may be disposed on the top surface 9u of the support substrate 9 and supported by the support substrate 9. The voltage measurement probe 5 may be provided in plural. For example, the plurality of voltage measurement probes 5 may be disposed on one support substrate 9. The plurality of voltage measurement probes 5 may be disposed spaced apart from each other in a horizontal direction (i.e., the second direction D2 and/or the third direction D3) on the support substrate 9. Unless otherwise especially stated, a single voltage measurement probe 5 will be discussed below.

The voltage measurement probe 5 may include a first electrode 51, a pattern plate 53, a dielectric wall 55, a second electrode 57, and a dielectric layer 52.

The first electrode 51 may be positioned on the support substrate 9. When the support substrate 9 includes a conductive material, such as one or more of silicon (Si) and metal, the dielectric layer 52 may further be positioned on the first electrode 51 and the support substrate 9. For example, the first electrode 51 may have a bottom surface 51b in contact with the dielectric layer 52. The first electrode 51 may include a conductive material. For example, the first electrode 51 may include silicon (Si), aluminum (Al), and/or copper (Cu). The first electrode 51 may have a circular shape when viewed in plan view. For example, the first electrode 51 may have a disk shape. The present inventive concepts, however, are not limited thereto, and the first electrode 51 may have any other suitable shapes. The first electrode 51 may be connected to the voltage measurement device 8. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. For example, the first electrode 51 may be electrically connected to a first voltage measurement device 81 which will be discussed below. The first electrode 51 may have a top surface 51u whose portion is exposed by the pattern plate 53. A detailed description thereof will be further discussed below.

The pattern plate 53 may be positioned on the first electrode 51. For example, the pattern plate 53 may be positioned on the top surface 51u of the first electrode 51. The pattern plate 53 may provide a pattern hole 53h. The pattern hole 53h may be downwardly recessed from a top surface 53u of the pattern plate 53. The pattern hole 53h may vertically penetrate (i.e., extend into or through) the pattern plate 53. The pattern hole 53h may expose a portion of the top surface 51u of the first electrode 51. The pattern hole 53h may have an aspect ratio, defined as a horizontal width w1 relative to a vertical height h1 (w1:h1), ranging from about 1:50 to about 1:300. The pattern hole 53h may be provided in plural. The plurality of pattern holes 53h may be disposed spaced apart from each other in a horizontal direction. However, a single pattern hole 53h will be discussed below. The pattern plate 53 may have a circular shape when viewed in plan view. For example, the pattern plate 53 may have a cylindrical shape. The pattern plate 53 may include a non-conductive material. For example, the pattern plate 53 may include one or more of aluminum oxide (Al₂O₃) and quartz (SiO₂). The present inventive concepts, however, are not limited thereto, and the pattern plate 53 may include a conductive material, such as silicon (Si).

The dielectric wall 55 may be combined (i.e., in contact) with a lateral (i.e., horizontal) surface of the pattern plate 53. For example, the dielectric wall 55 may be positioned outside the pattern plate 53. The term “outside the pattern plate 53” used in this description may indicate a side opposite to a central axis of the pattern plate 53 relative to an outer lateral surface of the pattern plate 53. For example, the dielectric wall 55 may be combined with an outer lateral surface of the pattern plate 53. In this configuration, the dielectric wall 55 may surround the pattern plate 53. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The dielectric wall 55 may surround the outer lateral surface of the pattern plate 53. The dielectric wall 55 may have a ring shape when viewed in plan. The dielectric wall 55 may have a hollow cylindrical shape. The dielectric wall 55 may have a height substantially the same as or similar to a sum of height of the first electrode 51 and height of the pattern plate 53, but the present inventive concepts are not limited thereto. The dielectric wall 55 may include a dielectric material. For example, the dielectric wall 55 may include one or more of aluminum oxide (Al₂O₃) and quartz (SiO₂).

On a side opposite to the pattern plate 53, the second electrode 57 may be combined with the dielectric wall 55. For example, the second electrode 57 may be combined with an outer lateral surface of the dielectric wall 55. The second electrode 57 may not overlap the pattern plate 53. The term “overlap” (or “overlapping,” or like terms), as may be used herein, is intended to broadly refer to a first element that intersects with at least a portion of a second element in the vertical direction (i.e., direction D1), but does not require that the first and second elements be completely aligned with one another in a horizontal plane (i.e., in the second direction D2 and/or the third direction D3). For example, when viewed in plan view, the second electrode 57 may not overlap the pattern plate 53. The second electrode 57 may not be positioned on the top surface 53u of the pattern plate 53. No conductive material may be disposed on the top surface 53u of the pattern plate 53. The second electrode 57 may not overlap the first electrode 51. For example, when viewed in plan view, the second electrode 57 may not overlap the first electrode 51. In some embodiments, the second electrode 57 may surround the pattern plate 53. The second electrode 57 may surround the dielectric wall 55. The second electrode 57 may have an annular shape that surrounds the dielectric wall 55. The second electrode 57 may be supported by the dielectric layer 52. A bottom surface 57b of the second electrode 57 may be positioned on a top surface of the dielectric layer 52. The second electrode 57 may include a conductive material. For example, the second electrode 57 may include at least one material selected from silicon (Si), aluminum (Al), and copper (Cu). The second electrode 57 may be connected to the voltage measurement device 8. For example, the second electrode 57 may be electrically connected to a second voltage measurement device 83 which will be discussed below. The bottom surface 57b of the second electrode 57 may be located at a lower level than that of the top surface 51u of the first electrode 51, relative to an upper surface of the support substrate 9 as a reference layer. A top surface 57u of the second electrode 57 may be located at a level substantially the same as or similar to that of the top surface 51u of the first electrode 51; that is, the top surface 57u of the second electrode 57 may be coplanar with the top surface of the first electrode 51. The present inventive concepts, however, are not limited thereto, and differently from that shown in FIG. 4, the bottom surface 57b of the second electrode 57 may be located at a higher level than that of the top surface 51u of the first electrode 51, relative to the upper surface of the support substrate 9. A detailed description thereof will be further discussed below. An exposed area of the first electrode 51 may be substantially the same as or similar to that of the second electrode 57. When viewed in plan view, a ratio of the exposed area of the first electrode 51 and the exposed area of the second electrode 57 may be about 1:1. The present inventive concepts, however, are not limited thereto.

The dielectric layer 52 may be positioned on the support substrate 9. The dielectric layer 52 may include a dielectric material, such as aluminum oxide (Al₂O₃) or quartz (SiO₂). The dielectric layer 52 may prevent one or both of the first electrode 51 and the second electrode 57 from being in direct contact with the support substrate 9.

The voltage measurement device 8 may measure a voltage of the first electrode 51 and a voltage of the second electrode 57. The voltage measurement device 8 may include a first voltage measurement device 81 and a second voltage measurement device 83.

The first voltage measurement device 81 may measure a difference in voltage between the first electrode 51 and the support substrate 9. One side of the first voltage measurement device 81 may be electrically connected to the first electrode 51. Another side of the first voltage measurement device 81 may be electrically connected to the support substrate 9. The first voltage measurement device 81 may include a first voltmeter 811 and a first load generator 813. The first voltmeter 811 may measure a difference in voltage between the first electrode 51 and the support substrate 9. The first load generator 813 may apply a load to the first electrode 51.

The second voltage measurement device 83 may measure a difference in voltage between the second electrode 57 and the support substrate 9. One side of the second voltage measurement device 83 may be electrically connected to the second electrode 57. Another side of the second voltage measurement device 83 may be electrically connected to the support substrate 9. The second voltage measurement device 83 may include a second voltmeter 831 and a second load generator 833. The second voltmeter 831 may measure a difference in voltage between the second electrode 57 and the support substrate 9. The second load generator 833 may apply a load to the second electrode 57.

FIG. 5 illustrates a flow diagram showing an example substrate charging measurement method according to some embodiments of the present inventive concepts.

Referring to FIG. 5, a substrate charging measurement method SS may be provided. The substrate charging measurement method SS may be a way of measuring a voltage in the substrate processing apparatus (see SA of FIG. 6) by using the voltage measurement assembly (see VA of FIG. 1) discussed with reference to FIGS. 1 to 4. The substrate charging measurement method SS may include inserting a voltage measurement assembly into a substrate processing apparatus (S1) and measuring a voltage (S2).

With reference to FIGS. 6 to 11, the following description will focus on the substrate charging measurement method SS of FIG. 5.

FIGS. 6 to 11 illustrate schematic diagrams showing a substrate charging measurement method according to the flow diagram of FIG. 5.

Referring to FIG. 6, a substrate processing apparatus SA may be provided. The substrate processing apparatus SA may perform an etching process and/or a deposition process on a substrate. The substrate processing apparatus SA may use plasma to process a substrate. The substrate processing apparatus SA may generate plasma in various ways. For example, the substrate processing apparatus SA may be a capacitively coupled plasma (CCP) apparatus and/or an inductively coupled plasma (ICP) apparatus. For convenience, the following will illustrate and discuss a CCP type substrate processing apparatus. The substrate processing apparatus SA may include a process chamber 1, a stage 7, a showerhead 3, a direct-current (DC) power generator 2, a radio-frequency (RF) power generator 4, a vacuum pump VP, and a gas supply GS.

The process chamber 1 may provide a process space 1h defined by interior walls of the process chamber 1. A substrate process may be performed in the process space 1h. The process space 1h may be isolated from an external space. During a substrate process, the process space 1h may be in a substantial vacuum state. The process chamber 1 may have a cylindrical shape, but the present inventive concepts are not limited thereto.

The stage 7 may be positioned in the process chamber 1. For example, the stage 7 may be positioned in the process space 1h. The stage 7 may support and/or fix a substrate. A substrate process may be performed in a state where a substrate is placed on the stage 7. The stage 7 will be further discussed in detail below.

The showerhead 3 may be positioned in the process chamber 1. For example, the showerhead 3 may be positioned in the process space 1h. The showerhead 3 may be disposed upwardly spaced apart from the stage 7. A gas supplied from the gas supply GS may be uniformly sprayed through the showerhead 3 into the process space 1h.

The DC power generator 2 may apply a DC power to the stage 7. The DC power applied from the DC power generator 2 may rigidly (i.e., fixedly) place a substrate on a certain position on the stage 7.

The RF power generator 4 may supply an RF power to the stage 7. It may thus be possible to control plasma in the process space 1h. A detailed description thereof will be further discussed below.

The vacuum pump VP may be connected to the process space 1h. The vacuum pump VP may apply a vacuum pressure to the process space 1h while a substrate process is performed.

The gas supply GS may supply the process space 1h with gas. The gas supply GS may include a gas tank, a compressor, and a valve. Plasma may be generated from a portion of gas supplied from the gas supply GS to the process space 1h.

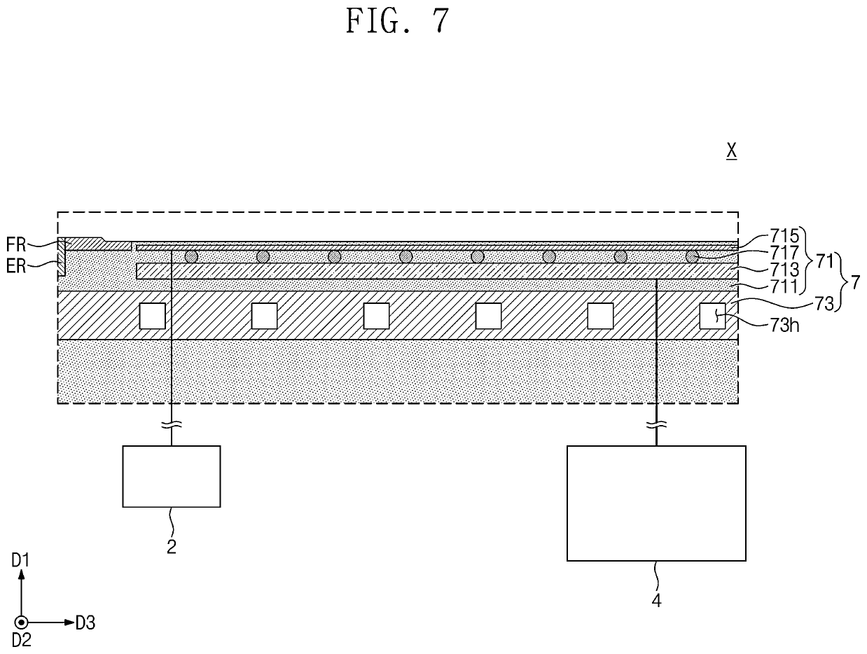

Referring to FIG. 7, which is an enlarged cross-sectional view of an area X in FIG. 6, the stage 7 may include a chuck 71 and a cooling plate 73.

A substrate and/or the voltage measurement assembly (see VA of FIG. 1) may be disposed on the chuck 71. The chuck 71 may fix a substrate and/or the voltage measurement assembly (see VA of FIG. 1) on a certain position. The chuck 71 may include a chuck body 711, a plasma electrode 713, a chuck electrode 715, and a heater 717.

The chuck body 711 may have a cylindrical shape. The chuck body 711 may include a ceramic, but the present inventive concepts are not limited thereto. A substrate may be disposed on a top surface of the chuck body 711. The chuck body 711 may be surrounded by a focus ring FR and/or an edge ring ER.

The plasma electrode 713 may be positioned in the chuck body 711. The plasma electrode 713 may include aluminum (Al). The plasma electrode 713 may have a disk shape, but the present inventive concepts are not limited thereto. An RF power may be applied to the plasma electrode 713. For example, the RF power generator 4 may apply the RF power to the plasma electrode 713. The RF power applied to the plasma electrode 713 may control the plasma in the process space (see 1h of FIG. 6).

The chuck electrode 715 may be positioned in the chuck body 711. The chuck electrode 715 may be located higher than (i.e., above) the plasma electrode 713. A DC power may be applied to the chuck electrode 715. For example, the DC power generator 2 may apply the DC power to the chuck electrode 715. The DC power applied to the chuck electrode 715 may fix a substrate and/or the voltage measurement assembly (see VA of FIG. 1) on a certain position on the chuck body 711. The chuck electrode 715 may include aluminum (Al), but the present inventive concepts are not limited thereto.

The heater 717 may be positioned in the chuck body 711. The heater 717 may be positioned between the chuck electrode 715 and the plasma electrode 713. The heater 717 may include a hot wire. For example, the heater 717 may include a concentrically circular shaped hot wire. The heater 717 may radiate heat to the surrounding environment. Therefore, the chuck body 711 may have an increased temperature.

The cooling plate 73 may be positioned beneath the chuck 71. For example, the chuck 71 may be positioned on the cooling plate 73. The cooling plate 73 may provide a cooling hole 73h. Cooling water may flow in the cooling hole 73h. The cooling water in the cooling hole 73h may absorb heat from the cooling plate 73.

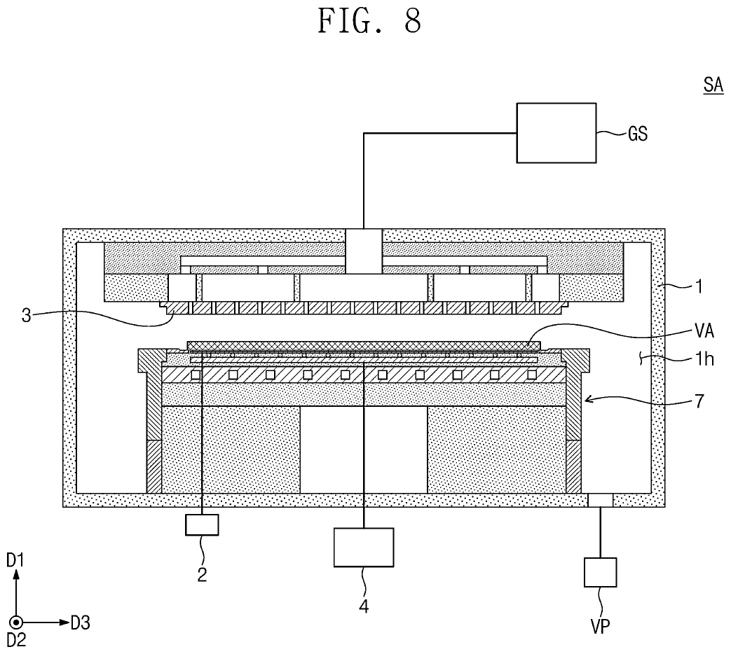

Referring to FIGS. 5 and 8, the insertion step S1 may include placing the voltage measurement assembly VA on the stage 7. For example, an electrostatic force may fix the voltage measurement assembly VA on the stage 7.

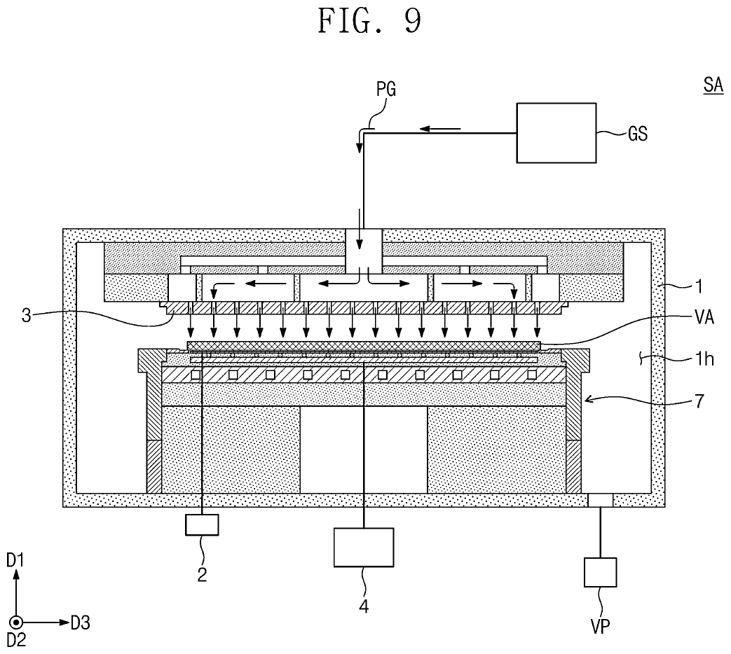

Referring to FIG. 9, a process gas PG may be provided to the process chamber 1. For example, the process gas PG supplied from the gas supply GS may be sprayed into the process space 1h (e.g., through an inlet provided in an exterior wall of the process chamber 1).

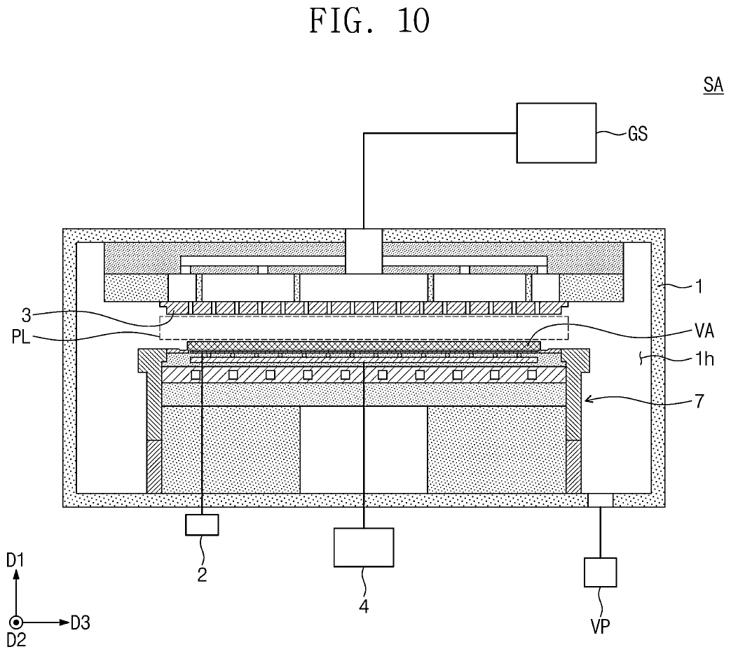

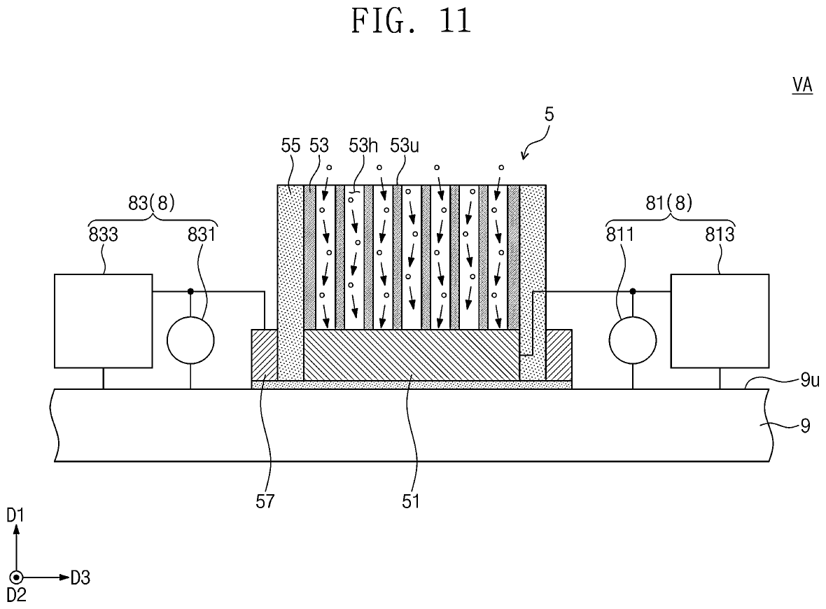

Referring to FIG. 10, a radio-frequency (RF) power may be applied to the stage 7 from the radio-frequency (RF) power generator 4, and thus a portion of the process gas (see PG of FIG. 9) in the process space 1h may be converted into plasma PL.

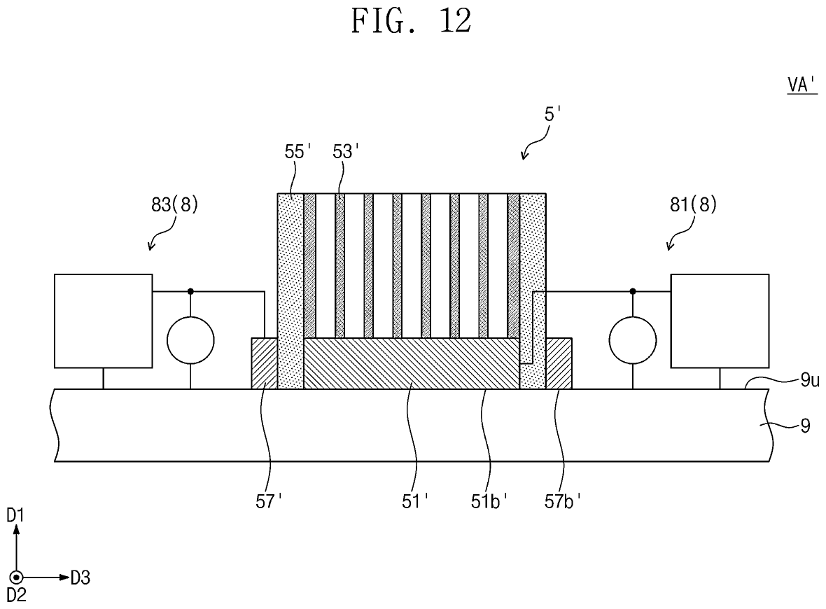

Referring to FIGS. 5 and 11, particles of the plasma (see PL of FIG. 10) may enter the pattern hole 53h. The voltage measurement step S2 may include measuring a voltage of the first electrode 51 and a voltage of the second electrode 57. For example, a difference in voltage may be measured between the first electrode 51 and the second electrode 57. This procedure may be performed by two voltage measurement devices 8. For example, the first voltage measurement device 81 may measure a difference in voltage between the first electrode 51 and the support substrate 9. The second voltage measurement device 83 may measure a difference in voltage between the second electrode 53 and the support substrate 9. It may thus be possible to measure the difference in voltage between the first electrode 51 and the second electrode 57.

The voltage measurement step S2 may further include providing a load to one or both of the first electrode 51 and the second electrode 57. For example, the first load generator 813 may apply a load to the first electrode 51. In addition, the second load generator 833 may apply a load to the second electrode 57. Therefore, it may be possible to compensate measurement value distortions that possibly occur during a measurement procedure or simulation of electrical characteristics of a process substrate.

It is illustrated and described that a difference in voltage between the first electrode 51 and the second electrode 57 is measured through the support substrate 9, but the present inventive concepts are not limited thereto. For example, one voltage measurement device 8 may directly measure a difference in voltage between the first electrode 51 and the second electrode 57.

According to a voltage measurement assembly and a substrate charging measurement method using the same in accordance with some embodiments of the present inventive concepts, a measurement process may be performed under an environment similar to that of an actual substrate etching process to thereby exactly estimate a substrate charging state during the actual substrate etching process. For example, a second electrode of the voltage measurement assembly may not cover a top surface of pattern plate, and this may not distort a pathway of plasma particles that enter a pattern hole. The term “cover” (or “covering,” “covers,” or like terms), as may be used herein, is intended to broadly refer to an element, structure or layer that is on or over another element, structure or layer, either directly or with one or more other intervening elements, structures or layers therebetween. In this configuration, as no conductive material is disposed on the pattern plate, it may be possible to make an electric field environment similar to that of an actual substrate etching process. Therefore, an accurate simulation of the actual substrate etching process may be allowed to obtain exact measurement results.

According to a voltage measurement assembly and a substrate charging measurement method using the same in accordance with some embodiments of the present inventive concepts, a voltage measurement probe is provided in plural, and thus measurement results for various positions may be obtained at once (i.e., concurrently).

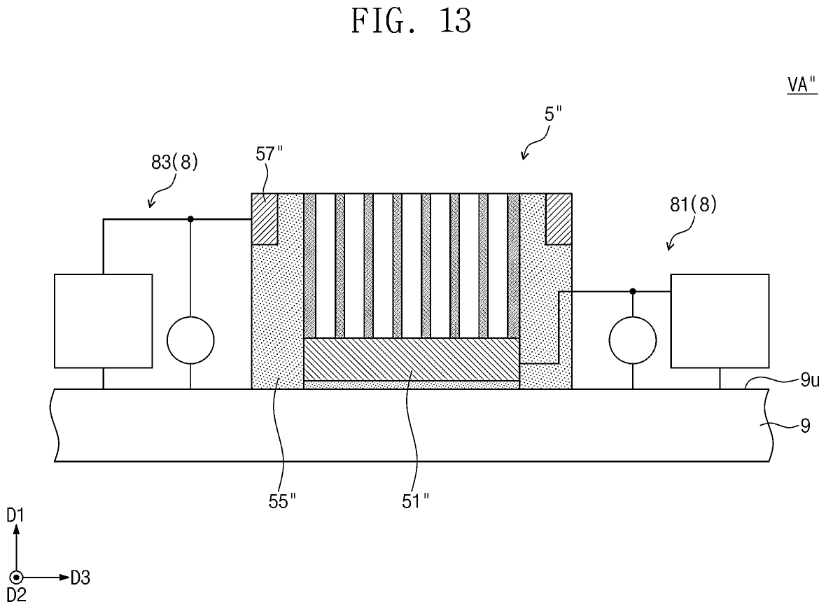

FIG. 12 illustrates a schematic side cross-sectional view partially showing a voltage measurement assembly according to some embodiments of the present inventive concepts.

The following will omit a description substantially the same as or similar to that discussed with reference to FIGS. 1 to 11.

Referring to FIGS. 12 to 14, a voltage measurement assembly VA′ may be provided. The voltage measurement assembly VA′ may include a support substrate 9, a voltage measurement device 8, and a voltage measurement probe 5′.

The voltage measurement probe 5′ may include a first electrode 51′, a pattern plate 53′, a dielectric wall 55′, and a second electrode 57′. Differently from that discussed with reference to FIG. 3, the voltage measurement probe 5′ of FIG. 12 may not include the dielectric layer (see 52 of FIG. 3). For example, each of the first electrode 51′, the dielectric wall 55′, and the second electrode 57′ may be in direct contact with the top surface 9u of the support substrate 9. In this case, the support substrate 9 may not include a conductive material.

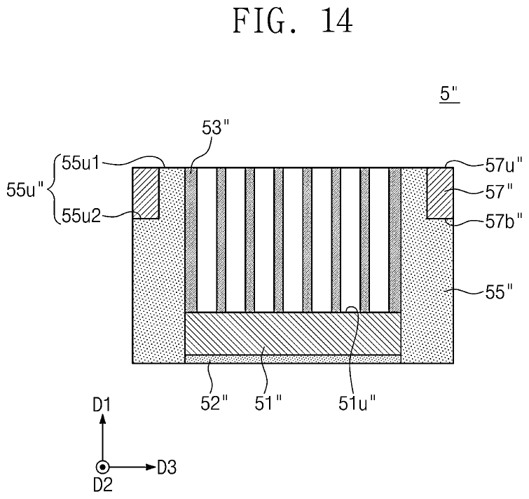

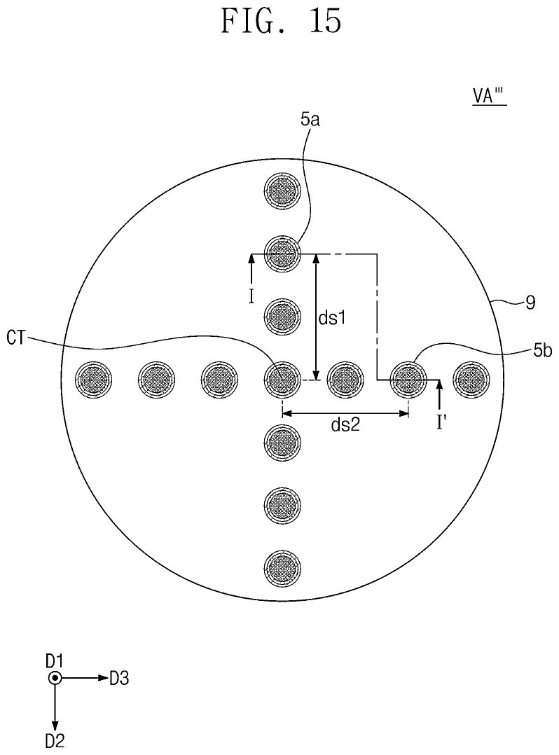

FIG. 13 illustrates a schematic side cross-sectional view partially showing a voltage measurement assembly according to some embodiments of the present inventive concepts. FIG. 14 illustrates a schematic side cross-sectional view showing a voltage measurement probe according to some embodiments of the present inventive concepts.

The following will omit a description of components substantially the same as or similar to those discussed with reference to FIGS. 1 to 12.

Referring to FIGS. 13 and 14, a voltage measurement assembly VA″ may be provided. The voltage measurement assembly VA″ may include a support substrate 9, a voltage measurement device 8, and a voltage measurement probe 5″.

The voltage measurement probe 5″ may include a first electrode 51″, a pattern plate 53″, a dielectric wall 55″, a second electrode 57″, and a dielectric layer 52″.

A bottom surface 57b″ of the second electrode 57″ may be located at a higher level than that of a top surface 51u″ of the first electrode 51″, relative to a top surface of the support substrate 9 as a reference layer. The bottom surface 57b″ of the second electrode 57″ may be supported by a top surface 55u″ of the dielectric wall 55″. The top surface 55u″ of the dielectric wall 55″ may include a first top surface 55u1 and a second top surface 55u2. The second top surface 55u2 may be located at a lower level than that of the first top surface 55u1. The bottom surface 57b″ of the second electrode 57″ may be supported by the second top surface 55u2. A top surface 57u″ of the second electrode 57″ may be located at a level substantially the same as or similar to (i.e., coplanar with) that of the first top surface 55u1, but the present inventive concepts are not limited thereto.

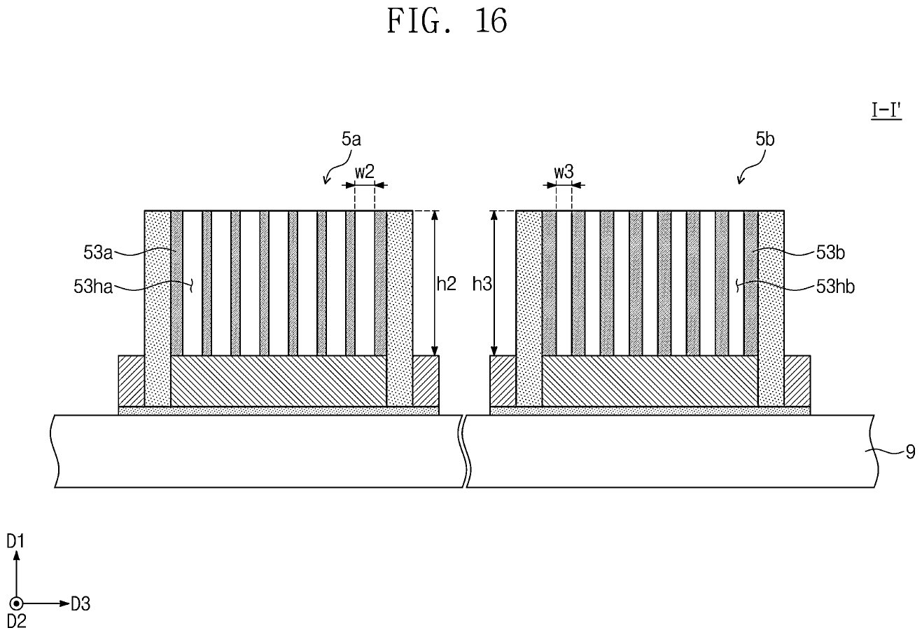

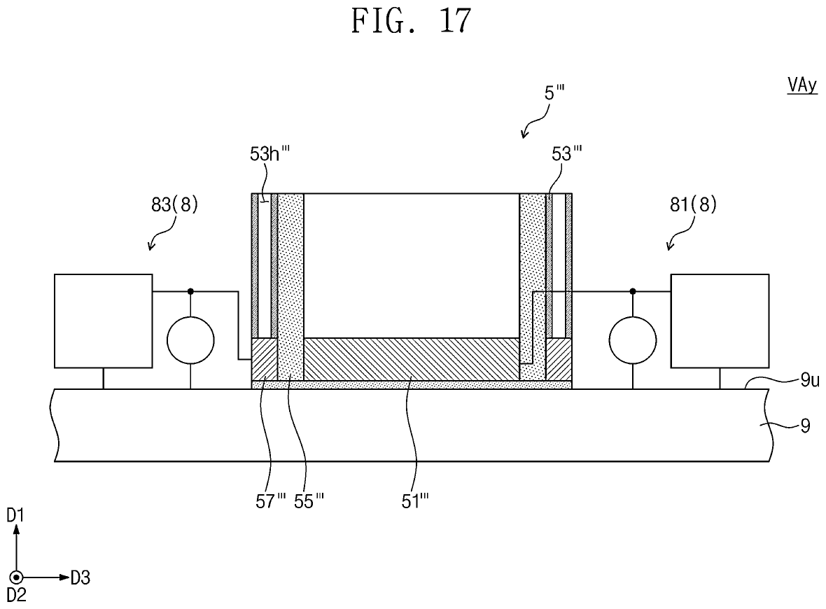

FIG. 15 illustrates a schematic plan view showing a voltage measurement assembly according to some embodiments of the present inventive concepts. FIG. 16 illustrates a schematic side cross-sectional view taken along line I-I′ of FIG. 15.

The following will omit a description of components substantially the same as or similar to those discussed with reference to FIGS. 1 to 14.

Referring to FIGS. 15 and 16, a plurality of voltage measurement probes may include a first voltage measurement probe 5a and a second voltage measurement probe 5b. The first voltage measurement probe 5a may be spaced apart at a first distance ds1 in the second direction D2 from a center CT of the support substrate 9. The second voltage measurement probe 5b may be spaced apart at a second distance ds2 in the third direction D3 from the center CT of the support substrate 9. The first distance ds1 and the second distance ds2 may be substantially the same as or similar to each other, but the present inventive concepts are not limited thereto.

A pattern hole 53ha of the first voltage measurement probe 5a may have an aspect ratio (w2:h2) different from an aspect ratio (w3:h3) of a pattern hole 53hb of the second voltage measurement probe 5b. The aspect ratio (w3:h3) of the pattern hole 53hb of the second voltage measurement probe 5b may be greater than the aspect ratio (w2:h2) of the pattern hole 53ha of the first voltage measurement probe 5a, although embodiments are not limited thereto.

According to a voltage measurement assembly and a substrate charging measurement method using the same in accordance with some embodiments of the present inventive concepts, a measurement result for various aspect ratios may be obtained in a one-time measurement that uses one voltage measurement assembly. When first and second distances are the same as each other, it may be possible to obtain a measurement result for two different aspect ratios which are the same distance from a center.

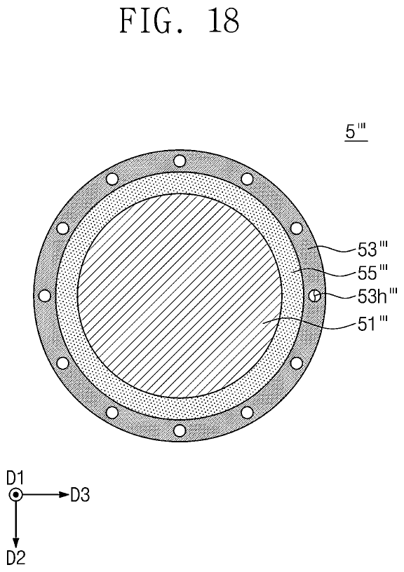

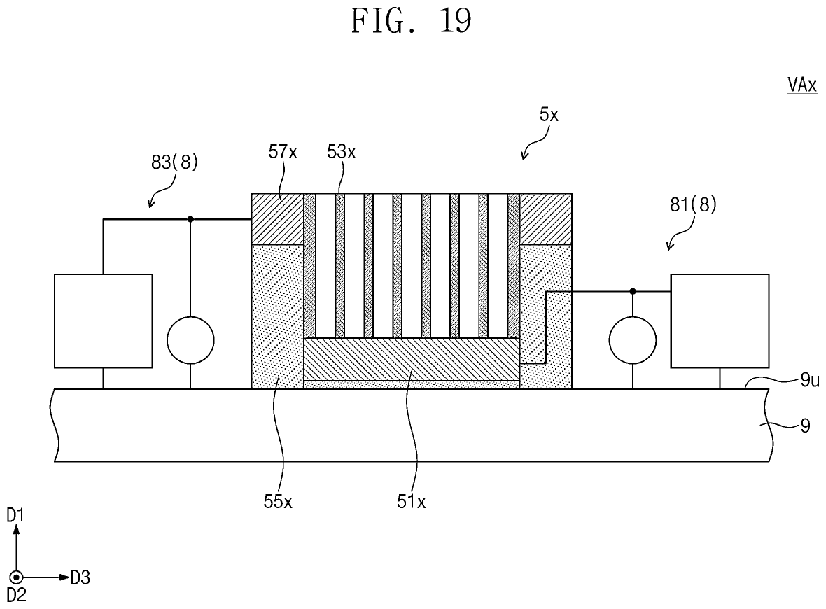

FIG. 17 illustrates a schematic side cross-sectional view partially showing a voltage measurement assembly according to some embodiments of the present inventive concepts. FIG. 18 illustrates a schematic plan view showing a voltage measurement probe according to some embodiments of the present inventive concepts.

The following will omit a description substantially the same as or similar to that discussed with reference to FIGS. 1 to 16.

Referring to FIGS. 17 and 18, a voltage measurement assembly VAy may be provided. The voltage measurement assembly VAy may include a support substrate 9, a voltage measurement device 8, and a voltage measurement probe 5′″.

The voltage measurement probe 5′″ may include a first electrode 51′″, a pattern plate 53′″, a dielectric wall 55′″, and a second electrode 57′″. The pattern plate 53′″ may be combined with a lateral surface of the dielectric wall 55′″. The pattern plate 53′″ may be positioned outside the dielectric wall 55′″. The pattern plate 53′″ may have an annular shape that surrounds the dielectric wall 55′″. The pattern plate 53′″ may be positioned on the second electrode 57′″. The pattern plate 53′″ may not vertically overlap the first electrode 51′″. Differently from that discussed with reference to FIG. 3, the pattern plate 53′″ may be positioned not on a center but an outside (i.e., perimeter).

FIG. 19 illustrates a schematic side cross-sectional view partially showing a voltage measurement assembly according to some embodiments of the present inventive concepts.

The following will omit a description substantially the same as or similar to that discussed with reference to FIGS. 1 to 18.

Referring to FIG. 19, a voltage measurement assembly VAx may be provided. The voltage measurement assembly VAx may include a support substrate 9, a voltage measurement device 8, and a voltage measurement probe 5x.

The voltage measurement probe 5x may include a first electrode 51x, a pattern plate 53x, a dielectric wall 55x, and a second electrode 57x. The second electrode 57x may be positioned on the dielectric wall 55x. The second electrode 57x may be in contact with the pattern plate 53x.

According to a voltage measurement assembly and a substrate charging measurement method using the same of the present inventive concepts, a substrate charging state may be estimated under an environment similar to that of a substrate etching process.

According to a voltage measurement assembly and a substrate charging measurement method using the same of the present inventive concepts, it may be possible to obtain at once a measurement result for various positions on a substrate.

According to a voltage measurement assembly and a substrate charging measurement method using the same of the present inventive concepts, it may be possible to obtain at once a measurement result for various aspect ratios.

According to a voltage measurement assembly and a substrate charging measurement method using the same of the present inventive concepts, it may be possible to eliminate measurement errors possibly occurring due to voltage distortion and/or simulation of electrical characteristics of an actual process substrate.

Effects of the present inventive concepts are not limited to the mentioned above, other effects which have not been mentioned above will be clearly understood to those skilled in the art from the following description.

Although the present invention has been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A voltage measurement assembly, comprising:
a support substrate; and
a voltage measurement probe on a top surface of the support substrate,
wherein the voltage measurement probe includes:
a first electrode;
a pattern plate;
a dielectric wall in contact with a lateral surface of the pattern plate; and
a second electrode in contact with the dielectric wall,
wherein the pattern plate includes a plurality of pattern holes that are downwardly recessed from a top surface of the pattern plate and vertically extend in the pattern plate, and
wherein the second electrode is vertically non-overlapping with respect to the first electrode.

2. The voltage measurement assembly of claim 1, wherein
the voltage measurement probe comprises a plurality of voltage measurement probes, and
the plurality of voltage measurement probes are spaced apart from each other in a horizontal direction on the top surface of the support substrate.

3. The voltage measurement assembly of claim 2, wherein the plurality of voltage measurement probes include a first voltage measurement probe and a second voltage measurement probe,
wherein an aspect ratio of each of the plurality of pattern holes in the first voltage measurement probe is different from an aspect ratio of each of the plurality of pattern holes in the second voltage measurement probe.

4. The voltage measurement assembly of claim 1, wherein each of the plurality of pattern holes has an aspect ratio ranging from about 1:50 to about 1:300.

5. The voltage measurement assembly of claim 1, wherein
the pattern plate is on the first electrode, and
the second electrode extends around the dielectric wall.

6. The voltage measurement assembly of claim 1, wherein
the pattern plate has a circular shape when viewed in plan view, and
the second electrode has an annular shape that extends around the dielectric wall.

7. The voltage measurement assembly of claim 1, wherein
each of the first electrode and the second electrode comprises silicon (Si), aluminum (Al), and/or copper (Cu), and
the pattern plate includes at least one selected from silicon (Si), aluminum oxide (Al₂O₃), and quartz (SiO₂).

8. The voltage measurement assembly of claim 1, wherein
the second electrode is vertically non-overlapping with respect to the pattern plate, when viewed in plan view, and
a conductive material is not on the top surface of the pattern plate.

9. The voltage measurement assembly of claim 1, wherein a bottom surface of the second electrode is at a level lower than a level of a top surface of the first electrode, relative to the top surface of the support substrate.

10. The voltage measurement assembly of claim 1, wherein
a bottom surface of the second electrode is at a level higher than a level of a top surface of the first electrode, relative to the top surface of the support substrate, and
the bottom surface of the second electrode is supported by a top surface of the dielectric wall.

11. A voltage measurement assembly, comprising:
a support substrate; and
a plurality of voltage measurement probes on the support substrate,
wherein each of the plurality of voltage measurement probes includes:
a first electrode;
a pattern plate on the first electrode;
a dielectric wall outside the pattern plate; and
a second electrode in contact with the dielectric wall,
wherein the pattern plate includes a plurality of pattern holes that vertically extend in the pattern plate to expose a top surface of the first electrode.

12. The voltage measurement assembly of claim 11, wherein the plurality of voltage measurement probes includes:
a first voltage measurement probe spaced apart at a first distance from a center of the support substrate; and
a second voltage measurement probe spaced apart at a second distance from the center of the support substrate,
wherein a first aspect ratio of at least one of the plurality of pattern holes in the first voltage measurement probe is different from a second aspect ratio of at least one of the plurality of pattern holes in the second voltage measurement probe.

13. The voltage measurement assembly of claim 12, wherein the first distance and the second distance are the same.

14. The voltage measurement assembly of claim 11, wherein
the dielectric wall has an annular shape that outwardly extends around the pattern plate, when viewed in plan view, and
the second electrode has an annular shape that outwardly extends around the dielectric wall, when viewed in plan view.

15. The voltage measurement assembly of claim 11, further comprising a voltage measurement device configured to measure a voltage of the first electrode and a voltage of the second electrode.

16. The voltage measurement assembly of claim 15, wherein the voltage measurement device includes:
a first voltage measurement device configured to measure the voltage of the first electrode; and
a second voltage measurement device configured to measure the voltage of the second electrode,
wherein a first end of the first voltage measurement device is electrically connected to the first electrode,
wherein a second end of the first voltage measurement device is electrically connected to the support substrate,
wherein a first end of the second voltage measurement device is electrically connected to the second electrode, and
wherein a second end of the second voltage measurement device is electrically connected to the support substrate.

17. The voltage measurement assembly of claim 11, wherein
the support substrate has a disk shape, and
a diameter of the support substrate is in a range of about 280 mm to about 320 mm.

18. A voltage measurement assembly, comprising:
a support substrate; and
a voltage measurement probe on a top surface of the support substrate,
wherein the voltage measurement probe includes:
a first electrode;
a pattern plate on the first electrode;
a second electrode surrounding the pattern plate; and
a dielectric wall interposed between the second electrode and the pattern plate;
wherein the pattern plate includes a plurality of pattern holes that vertically extend in the pattern plate to expose a top surface of the first electrode.

19. The voltage measurement assembly of claim 18, wherein
the voltage measurement probe comprises a plurality of voltage measurement probes, and
the plurality of voltage measurement probes include a first voltage measurement probe and a second voltage measurement probe which are spaced apart from each other in a horizontal direction on the top surface of the support substrate,
wherein an aspect ratio of each of the plurality of pattern holes in the first voltage measurement probe is different from an aspect ratio of each of the plurality of pattern holes in the second voltage measurement probe.

20. The voltage measurement assembly of claim 18, wherein the upper surface of the second electrode is at a level equal to or lower than the level of the upper surface of the pattern plate, relative to the top surface of the support substrate.
